(19) United States
(12) Patent Application Publication
(10) Pub. No.: US 2025/0157993 A1
(43) Pub. Date: May 15, 2025

(54) DISPLAY DEVICE

(71) Applicant: SAMSUNG DISPLAY CO., LTD., YONGIN-SI (KR)

(72) Inventor: JINHYOUNG KIM, Yongin-si (KR)

(21) Appl. No.: 18/765,402

(22) Filed: Jul. 8, 2024

(30) Foreign Application Priority Data
Nov. 13, 2023 (KR) 10-2023-0156355

(51) Int. Cl. H01L 25/075; G06F 1/16; H01L 33/54

(52) U.S. Cl. CPC H01L 25/0753; G06F 1/1652; H10H 20/853

(57) ABSTRACT

A display device includes a substrate including a display region and a non-display region, a display layer disposed on the substrate and overlapping the display region, a cover spacer disposed on the substrate and comprising metal, and a first adhesive layer disposed between the cover spacer and the substrate, wherein an edge of the cover spacer and an edge of the first adhesive layer overlap each other.

### CROSS-REFERENCE TO RELATED APPLICATION

This application claims priority under 35 U.S.C. § 119 to Korean Patent Application No. 10-2023-0156355, filed at the Korean Intellectual Property Office on Nov. 13, 2023, the disclosure of which is incorporated by reference herein in its entirety.

### (a) TECHNICAL FIELD

Embodiments of the present invention relate to a display device.

### (b) DISCUSSION OF THE RELATED ART

Generally, a display device includes pixels and displays an image on a display screen by controlling the brightness of each pixel.

A display device may include a touch sensing unit and a display panel. The touch sensing unit may detect a user's touch, and the display panel may include pixels.

The touch sensor may be provided on the display panel.

For example, the display panel includes a touch sensor or a panel including a touch sensor attached to the display panel.

The display device may include a flexible printed circuit board responsible for transmitting signals to drive both pixels and the touch sensor on the display panel.

### SUMMARY

According to an embodiment of the present invention, a display device includes: a substrate including a display region and a non-display region; a display layer disposed on the substrate and overlapping the display region; a cover spacer disposed on the substrate and including metal; and a first adhesive layer disposed between the cover spacer and the substrate, wherein an edge of the cover spacer and an edge of the first adhesive layer overlap each other.

In an embodiment of the present invention, the substrate includes: a first region where the display layer is disposed; a second region bending and extending from the first region; and a third region connected to the second region and overlapping the first region.

In an embodiment of the present invention, the display device further includes: a second adhesive layer disposed between the third region and the cover spacer, wherein the first adhesive layer is disposed between the first region and the cover spacer.

In an embodiment of the present invention, the edge of the first adhesive layer, the edge the cover spacer, and an edge of the second adhesive layer are aligned with each other.

In an embodiment of the present invention, the edges of the cover spacer and an edge of the second adhesive layer are aligned with each other.

In an embodiment of the present invention, the edge of the first adhesive layer and the edge of the cover spacer are spaced apart from each other.

In an embodiment of the present invention, the edge of the first adhesive layer does not overlap the edge of the cover spacer.

In an embodiment of the present invention, the second adhesive layer covers the cover spacer.

In an embodiment of the present invention, the second adhesive layer exposes at least a portion of the cover spacer.

In an embodiment of the present invention, the cover spacer includes: a first cover region overlapping the second adhesive layer; and a second cover region exposed by the second adhesive layer.

In an embodiment of the present invention, the display device further includes: a support plate positioned between the substrate and the cover spacer.

According to an embodiment of the present invention, a display device includes: a substrate including a first region, a second region, and a third region; a display layer disposed on the first region of the substrate; a cover spacer disposed between the first region and the third region, and including metal; and a second adhesive layer disposed between the cover spacer and the third region, wherein at least a portion of the second adhesive layer and the cover spacer have a same shape as each other.

In an embodiment of the present invention, the second region extends from the first region and is bent, and the third region is connected to the second region and overlaps a rear surface of the first region.

In an embodiment of the present invention, the display device further includes a first adhesive layer positioned between the first region and the cover spacer.

In an embodiment of the present invention, edges of the first adhesive layer, the cover spacer, and the second adhesive layer are aligned with each other.

In an embodiment of the present invention, an edge of the cover spacer and an edge of the second adhesive layer are aligned with each other.

In an embodiment of the present invention, an edge of the first adhesive layer and the edge of the cover spacer are spaced apart from each other.

In an embodiment of the present invention, the edge of the first adhesive layer does not overlap the edge of the cover spacer.

In an embodiment of the present invention, the second adhesive layer completely covers the cover spacer.

In an embodiment of the present invention, the second adhesive layer exposes at least a portion of the cover spacer.

### BRIEF DESCRIPTION OF THE DRAWINGS

FIG. 1 is a schematic perspective view of a display device according to an embodiment of the present invention.

FIG. 2 is a cross-sectional view of a portion of a display device according to an embodiment of the present invention.

FIG. 3 is a cross-sectional view of a cover spacer according to an embodiment of the present invention.

FIG. 4 is a cross-sectional view of a portion of a display device according to an embodiment of the present invention.

FIG. 5 is a cross-sectional view of a cover spacer according to an embodiment of the present invention.

FIG. 6 is a top view of a cover spacer according to an embodiment of the present invention.

FIG. 7 is a plan view of a cover spacer according to an embodiment of the present invention.

FIG. 8, FIG. 9, FIG. 10, and FIG. 11 are diagrams of a method of manufacturing a display device according to an embodiment of the present invention.

### DETAILED DESCRIPTION OF THE EMBODIMENTS

Hereinafter, with reference to the attached drawings, embodiments of the present invention will be described in detail.

The present invention may be implemented in many different forms and is not limited to the embodiments described herein.

Identical or similar components are assigned the same reference numerals throughout the specification and drawings.

In the drawings, various thicknesses, lengths, and angles are shown and while the arrangement shown does indeed represent an embodiment of the present invention, it is to be understood that modifications of the various thicknesses, lengths, and angles may be possible within the spirit and scope of the present invention and the present invention is not necessarily limited to the particular thicknesses, lengths, and angles shown. When a layer, membrane, region, or plate is said to be “above” or “on” another layer, membrane, region, or plate, this includes not only cases where the layer, membrane, region, or plate is “directly above” or “directly on” the other layer, membrane, region, or plate, but also cases where intervening layers, membranes, regions, or plates may be present therebetween.

When an element is said to be “right on top” of another element, it means that no intervening elements are present therebetween.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly. Throughout the specification, the phrase “on a plane” means that the target portion is viewed from above, and the phrase “in cross-section” means that a cross-section of the target portion is cut vertically and viewed from the side.

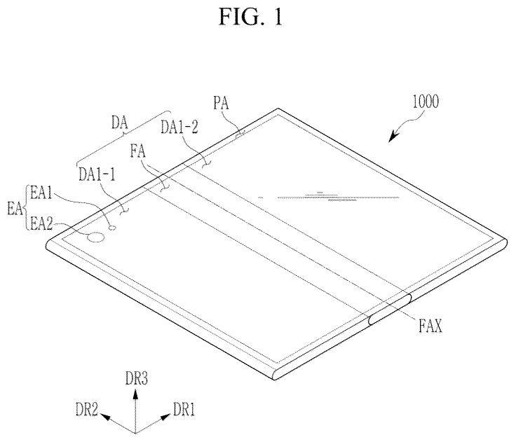

Hereinafter, a display device according to an embodiment of the present invention will be described with reference to FIG. 1.

FIG. 1 is a schematic perspective view of a display device according to an embodiment of the present invention.

The embodiment of FIG. 1 illustrates a foldable display device in which the display device 1000 is folded along a folding axis FAX.

Referring to FIG. 1, a display device 1000 according to an embodiment of the present invention is a device that displays moving images or still images, and may be used in, for example, a mobile phone, a smart phone, a tablet personal computer, or a mobile phone. In addition, the display device 1000 may be used in portable electronic devices such as communication terminals, electronic notebooks, e-books, portable multimedia player (PMP), navigation, ultra mobile PC (UMPC), as well as televisions, laptops, monitors, billboards, internet of things (IoT), etc.,

In addition, the display device 1000 according to an embodiment of the present invention may be included in a wearable device such as a smart watch, a watch phone, an eyewear display, and a head-mounted display (HMD).

In addition, the display device 1000 according to an embodiment of the present invention may be used in, for example, a dashboard of a car, a center information display (CID) that is placed on the center fascia or dashboard of a car, and a room mirror display (a room mirror display instead of a side mirror of a car), and may also be used as entertainment for the back seat of a car, or as a display that is placed on the back of the front seat.

FIG. 1 illustrates the display device 1000 being in a smart phone for convenience of explanation and as an example.

The display device 1000 may display an image in a third direction DR3 from a display surface, which is parallel to each of a first direction DR1 and a second direction DR2.

The display surface, on which the image is displayed, may correspond to the front surface of the display device 1000 and the front surface of a cover window CW.

Images may include static images as well as dynamic images.

In this embodiment, the front (or, e.g., top) and back (or, e.g., bottom) surfaces of each member are defined based on the direction in which the image is displayed.

The front and back surfaces are opposite to each other in the third direction DR3, and the normal directions of each of the front and back surfaces may be parallel to the third direction DR3.

The separation distance between the front and back surfaces in the third direction DR3 may correspond to the thickness of the display panel in the third direction DR3.

The display device 1000 according to an embodiment of the present invention may detect a user's input that is applied from the outside.

The user's input may include various types of external inputs, such as a touch from a part of the user's body, light, heat, or pressure.

In an embodiment of the present invention, a touch from the user's hand that is applied to the front surface is shown as the user's input.

However, the present invention is not necessarily limited to this.

The user's input may be provided in various forms, and the display device 1000 may also detect the user's input that is applied to the side surface or back surface of the display device 1000 depending on the structure of the display device 1000.

Referring to FIG. 1, in an embodiment of the present invention, the display device 1000 may be a foldable display device.

The display device 1000 may be folded outward or inward based on a folding axis FAX.

When folded outward based on the folding axis FAX, the display surfaces of the display device 1000 are positioned on the outside along the third direction DR3 so that images may be displayed in both directions (e.g., opposite directions). For example, when folded outward based on the folding axis FAX, the display surface may be visible on both sides.

When folded inward based on the folding axis FAX, the display surface might not be visible from the outside.

In an embodiment of the present invention, the display device 1000 may include a display region DA, a component region EA, and a non-display region PA.

The display region DA may be divided into a 1-1 display region DA1-1, a 1-2 display region DA1-2, and a folding region FA.

The 1-1 display region DA1-1 and the 1-2 display region DA1-2 may be disposed on the left and right sides, respectively, in relation to the folding axis FAX. For example, the folding region FA may be disposed between the 1-1 display region DA1-1 and the 1-2 display region DA1-2.

Accordingly, when folded outward along the folding axis FAX, the 1-1 display region DA1-1 and the 1-2 display region DA1-2 are positioned on front and back sides along the third direction DR3, allowing images to be displayed in both directions.

Additionally, when folded inward along the folding axis FAX, the 1-1 display region DA1-1 and the 1-2nd display region DA1-2 might not be visible from the outside.

The component region EA may include a first component region EA1 and a second component region EA2.

The first component region EA1 and the second component region EA2 may be at least partially surrounded by the display region DA.

The first component region EA1 and the second component region EA2 may be spaced apart from each other, but are not necessarily limited thereto. For example, the first component region EA1 and the second component region EA2 may be at least partially connected to each other.

The first component region EA1 and the second component region EA2 may be regions in which an optical element that uses, for example, infrared light, visible light, or sound is placed. For example, the optical element may be disposed below the first component region EA1 and the second component region EA2.

The display region DA and the component region EA are formed with a plurality of light emitting diodes and a plurality of pixel circuit units. The plurality of light emitting diodes and the plurality of pixel circuit units generate and transmit light emission current to each of the plurality of light emitting diodes.

Here, a light emitting diode and a pixel circuit unit are called a pixel. A pixel circuit unit and a light emitting diode may be formed in a one-to-one ratio in the display region DA and the component region EA.

A non-display region PA is disposed adjacent to the display region DA and may at least partially surround the display region DA.

An image is not displayed in the non-display region PA, and a driving circuit and/or driving wiring for driving the display region DA may be disposed in the non-display region PA.

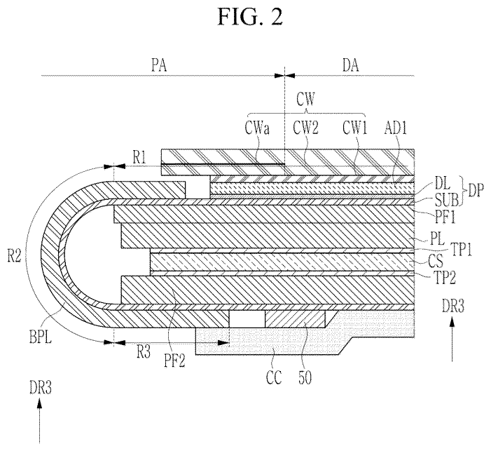

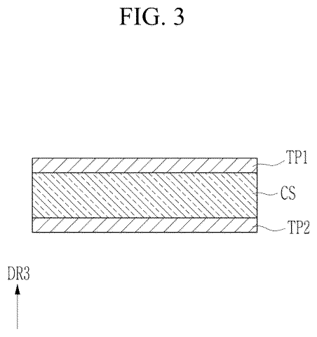

Hereinafter, a display device according to an embodiment of the present invention will be described with reference to FIGS. 2 and 3.

FIG. 2 is a cross-sectional view of a portion of a display device according to an embodiment of the present invention. FIG. 3 is a cross-sectional view of a cover spacer according to an embodiment of the present invention.

FIG. 2 schematically illustrates a region where a substrate SUB is bent within the non-display region PA according to an embodiment of the present invention.

A cover window CW may be disposed on a display panel DP that includes the substrate SUB and a display layer DL that is disposed on the substrate SUB. A cover window CW may be disposed on top of the display layer DL.

The cover window CW may at least partially cover an upper surface of the display layer DL.

The cover window CW may protect the upper surface of the display layer DL.

The cover window CW may include a base layer CW1 and a protective layer CW2.

In an embodiment of the present invention, the base layer CW1 may include a transparent material such as glass, a transparent synthetic resin, etc.

The base layer CW1 may include at least one layer.

The protective layer CW2 may be disposed on the upper surface of the base layer CW1 and may prevent or minimize scratches on the base layer CW1.

An opaque layer CWa may be disposed on a portion of the protective layer CW2.

In an embodiment of the present invention, the opaque layer CWa may be disposed at the edge of the protective layer CW2.

The opaque layer CWa may block light.

The opaque layer CWa may include a pattern that may be visible to the user when an image is not displayed.

The cover window CW may be coupled to the display layer DL by a first adhesive layer AD1.

The first adhesive layer AD1 may be a transparent adhesive member such as a pressure-sensitive adhesive (PSA) or an optically clear adhesive (OCA) film.

A stacked structure of the display layer DL may include a driving device layer, a light emitting device layer, and an encapsulation layer disposed on the substrate SUB.

The substrate SUB may be a base substrate or a base member.

The substrate SUB may be a flexible substrate including a polymer resin such as polyimide, polyamide, or polyethylene terephthalate.

A driving element layer may be disposed on the substrate SUB.

The driving element layer may include transistors and capacitors that constitute pixel circuit units which supply driving currents to light emitting devices.

The driving element layer may include gate lines, data lines, power lines, gate control lines, fan-out lines connecting the display driver and the data lines to each other, and lead lines connecting the display driver and the display pads to each other, etc.

The driving element layer may include transistors and capacitors constituting the gate driver and gate control lines.

The driving element layer may include conductive layers, semiconductor layers, and insulating layers. The conductive layers and semiconductive layers may form the transistors, capacitors, and signal lines, and the insulating layers may insulate the transistors, capacitor and signal lines

The light emitting device layer may be disposed on the driving device layer and may include light emitting devices and corresponding light emitting regions.

In addition, the light emitting device layer may include a pixel defining layer having openings, which define light emitting regions.

The encapsulation layer (also referred to as a thin film encapsulation layer) may cover the top and side surfaces of the light emitting device layer, and may prevent moisture or oxygen from penetrating into the light emitting device layer from the outside.

The encapsulation layer may include one or more inorganic layers and one or more organic layers.

The touch sensing unit may be disposed on the encapsulation layer and may include sensing electrodes.

The sensing electrodes may sense the user's touch by using a mutual capacitor method and/or a magnetic capacitor method.

In this specification, the configuration including the above-described driving device layer, light emitting device layer, encapsulation layer, and touch sensing unit is simply indicated as the display layer DL, and any one of these may be omitted.

The substrate SUB according to an embodiment of the present invention may include a first region R1, a second region R2, and a third region R3.

The display layer DL may be disposed on the first region R1.

The second region R2 may be disposed between the first region R1 and the third region R3.

The second region R2 may be bent.

The third region R3 may overlap the first region R1 since the second region R2 is bent.

A bending protection layer BPL may be disposed on the second region R2 where the substrate SUB is bent. The bending protection layer BPL may prevent formation of cracks in the substrate SUB.

The bending protection layer BPL may include a polymer resin such as polyethylene terephthalate (PET), polyimide (PI), etc.

A portion of the substrate SUB may be bent and positioned on the rear surface of the display layer DL.

A driving unit 50 may be disposed below the display layer DL. Additionally, the bending protection layer BPL, the driver 50, and a portion of the substrate SUB may be at least partially covered by a cover CC. For example, the driving unit 50 may be disposed between the display layer DL and the cover CC.

The cover CC may cover at least a portion of the driving unit 50 and the flexible printed circuit board), and thus, may protect the driving unit 50 and the flexible printed circuit board from electromagnetic interference EMI and electrostatic discharge ESD.

Additionally, the cover CC may prevent the driving unit 50 and the like from coming into direct contact with external objects, and thus, may protect them from physical damage due to friction.

A support plate PL may be disposed below the first region R1 of the substrate SUB.

The support plate PL may include a material with high rigidity such as copper, stainless steel (SUS), aluminum (Al), graphite, carbon fiber reinforced plastic (CFRP), glass fiber reinforced plastic (GFRP), glass, etc.

Carbon fiber reinforced plastic (CFRP) is a plastic that is hardened by impregnating carbon fiber (CF) with resin, and glass fiber reinforced plastic (GFRP) is a material that combines glass fiber and a thermosetting resin such as unsaturated polyester and epoxy resin.

The support plate PL may protect the display layer DL during the manufacturing process of the display device.

Protective layers PF1 and PF2 may be positioned on one side of the first region R1 and one side of the third region R3 of the substrate SUB, respectively.

The protective layers PF1 and PF2 may protect the display panel DP during the manufacturing process of the display device.

The protective layers PF1 and PF2 may protect the display panel DP from the environmental factors such as shock, electromagnetic waves, and noise.

Each of the protective layers PF1 and PF2 may include, for example, a shielding layer, a support layer, a cushion layer, etc., depending on the embodiment.

The protective layers PF1 and PF2 may include the first protective layer PF1 disposed between the first region R1 of the substrate SUB and the support plate PL, and a second protective layer PF2 disposed between the third region R3 of the substrate SUB and the cover spacer CS.

The protective layers PF1 and PF2 might not overlap the second region R2 of the substrate SUB.

According to an embodiment of the present invention, the cover spacer CS may be disposed between the first region R1 and the third region R3 of the substrate SUB.

The cover spacer CS may absorb external shock and prevent the display layer DL from being damaged.

The cover spacer CS may include a metal that provides sufficient rigidity.

The cover spacer CS may be disposed between the support plate PL and the third region R3.

For example, the cover spacer CS may be disposed on the support plate PL. For example, the cover spacer CS may be disposed on a back surface of the support plate PL.

The cover spacer CS may disposed between the first protective layer PF1 and the second protective layer PF2.

The cover spacer CS may be coupled to the first region R1 of the substrate SUB through a first adhesive layer TP1.

The cover spacer CS may be coupled to the support plate PL through the first adhesive layer TP1.

The first adhesive layer TP1 may be disposed between the first region R1 of the substrate SUB and the cover spacer CS.

The first adhesive layer TP1 may be disposed between the support plate PL and the cover spacer CS.

Additionally, the cover spacer CS may be coupled to the third region R3 of the substrate SUB through a second adhesive layer TP2.

The second adhesive layer TP2 may be positioned between the third region R3 of the substrate SUB and the cover spacer CS.

The second adhesive layer TP2 may be positioned between the second protective layer PF2 and the cover spacer CS.

According to an embodiment of the present invention, the edges of the first adhesive layer TP1, the cover spacer CS, and the second adhesive layer TP2 may be substantially aligned with each other as shown in FIGS. 2 and 3. For example, side surfaces of the first adhesive layer TP1, cover spacer CS, and second adhesive layer TP2 may be substantially coplanar.

During the manufacturing process, the first adhesive layer TP1, the cover spacer CS, and the second adhesive layer TP2 may be formed in a single process by using a device capable of cutting metal and insulating tape.

Accordingly, the first adhesive layer TP1, the cover spacer CS, and the second adhesive layer TP2 may have edges that are aligned with each other.

According to an embodiment of the present invention, the first adhesive layer TP1, the cover spacer CS, and the second adhesive layer TP2, which have edges that overlap each other, are easily attached to the support plate PL, making the manufacturing process easier. Thus, the reliability of the display device can be increased.

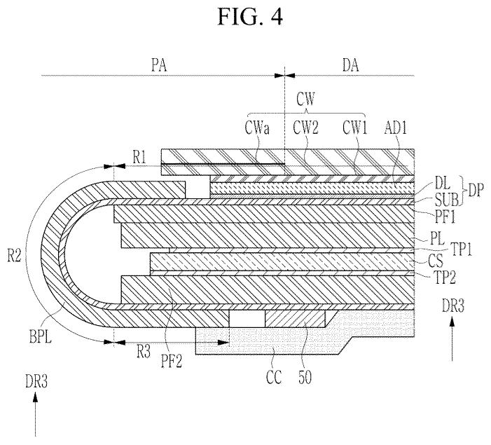

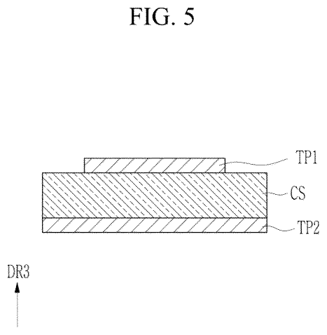

Hereinafter, a display device according to an embodiment of the present invention will be described with reference to FIGS. 4 and 5.

FIG. 4 is a cross-sectional view of a portion of a display device according to an embodiment of the present invention, and FIG. 5 is a cross-sectional view of a cover spacer according to an embodiment of the present invention.

To the extent that an element has not been described in detail, it may be assumed that the element is at least similar to corresponding elements that have been described in previous figures.

Referring to FIGS. 4 and 5, the display device according to an embodiment of the present invention may include a first adhesive layer TP1 disposed between the cover spacer CS and the support plate PL, a second protective layer PF2, and a second adhesive layer TP2 disposed between the cover spacer CS and the second protective layer PF2.

The edge of the first adhesive layer TP1 may be positioned adjacent to the edge of the cover spacer CS. For example, the first adhesive layer TP1 and the cover spacer CS may be arranged in a staircase configuration, with the edge of the first adhesive layer TP1 not extending beyond the edge of the cover spacer CS and being a predetermined distance from the edge of the cover spacer CS. In this configuration, the first adhesive layer TP1 and the cover spacer CS are layered in such a way that the edges of the first adhesive layer TP1 are positioned within the boundary of the cover spacer CS, creating a tiered effect.

The cover spacer CS may protrude beyond the first adhesive layer TP1.

As shown in FIG. 5, the first adhesive layer TP1 may have a width smaller than the width of the cover spacer CS.

The edge of the second adhesive layer TP2 may be aligned with the edge of the cover spacer CS.

The ends of the second adhesive layer TP2 and the cover spacer CS may overlap each other.

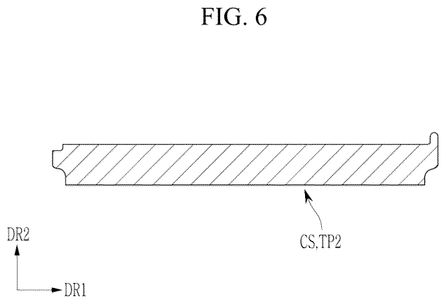

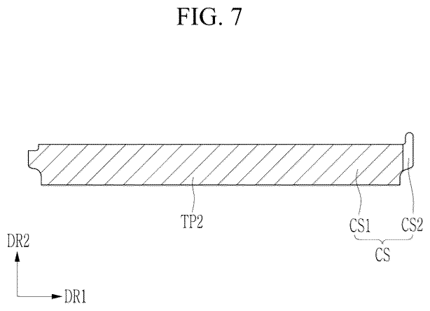

Hereinafter, a cover spacer according to an embodiment of the present invention will be described with reference to FIGS. 6 and 7.

FIG. 6 is a plan view of a cover spacer according to an embodiment of the present invention, and FIG. 7 is a plan view of a cover spacer according to embodiment of the present invention.

To the extent that an element has not been described in detail, it may be assumed that the element is at least similar to corresponding elements that have been described in previous figures.

FIG. 6 is a diagram illustrating the second adhesive layer TP2 coupled to the cover spacer CS according to an embodiment of the present invention.

The second adhesive layer TP2 may have the exact same planar shape as that of the cover spacer CS.

The second adhesive layer TP2 may cover the cover spacer CS. For example, the second adhesive layer TP2 may completely cover the cover space CS.

The edges of the second adhesive layer TP2 may overlap edges of the cover spacer CS. For example, all edges of the second adhesive layer TP2 may overlap all the edges of the cover spacer CS.

The second adhesive layer TP2 and the cover spacer CS may be manufactured through a single manufacturing process.

FIG. 7 is a diagram illustrating the second adhesive layer TP2 coupled to the cover spacer CS according to embodiment of the present invention.

The second adhesive layer TP2 may expose at least a portion of the cover spacer CS.

The cover spacer CS may include a first cover region CS1, which overlaps the second adhesive layer TP2, and a second cover region CS2, which is not covered by the second adhesive layer TP2.

In embodiments of the present invention, the second cover region CS2 exposed by the second adhesive layer TP2 may be used in an inspection process.

As an example, the inspection process may be a process of measuring surface resistance or inspecting ground function.

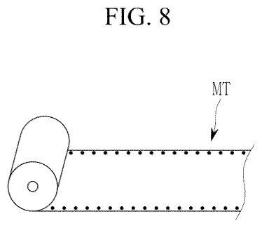

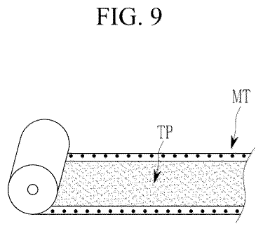

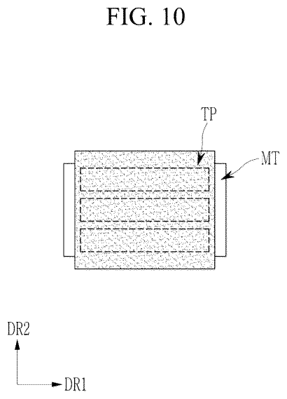

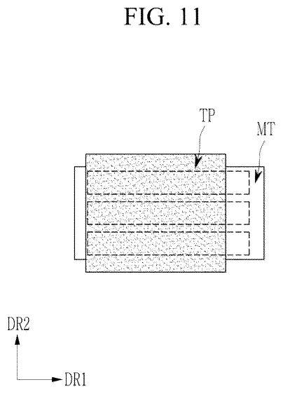

Hereinafter, a method of manufacturing a display device according to an embodiment of the present invention will be described with reference to FIGS. 8 to 11.

FIG. 8, FIG. 9, FIG. 10, and FIG. 11 are diagrams of a method of manufacturing a display device according to an embodiment.

In particular, the manufacturing process of the cover spacer and the adhesive layer will be described below.

To the extent that an element has not been described in detail, it may be assumed that the element is at least similar to corresponding elements that have been described in previous figures.

First, referring to FIGS. 8 and 9, a metal fabric MT forming a cover spacer and an adhesive fabric TP forming an adhesive layer are prepared.

Then, the adhesive fabric TP is laminated on the metal fabric MT.

This specification describes an example of a double-layer structure in which one adhesive fabric TP is disposed on a metal fabric MT, but the present invention is not necessarily limited thereto. For example, the adhesive fabric TP, metal fabric MT, and adhesive fabric may be laminated to form a three-layer structure.

Additionally, in the process of laminating the metal fabric MT and the adhesive fabric TP, guide holes may be formed along each lamination edge to accurately align the metal fabric MT and the adhesive fabric TP with each other.

Thereafter, as shown in FIG. 10, a cover spacer and a second adhesive layer of the same planar shape can be formed as shown in FIG. 6 by using a mold that can simultaneously cut the metal fabric MT and adhesive fabric TP.

In addition, as shown in FIG. 11, a cutting process may be performed to expose a portion of the cover spacer as shown in FIG. 7 depending on the arrangement of the adhesive fabric TP.

When the metal cover spacer and the adhesive layer are formed simultaneously, as in the manufacturing method according to an embodiment of the present invention, the cover spacer and the adhesive layer may be easily aligned and the reliability of the process can be increased.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a substrate including a display region and a non-display region;
a display layer disposed on the substrate and overlapping the display region;
a cover spacer disposed on the substrate and comprising metal; and
a first adhesive layer disposed between the cover spacer and the substrate, wherein an edge of the cover spacer and an edge of the first adhesive layer overlap each other.

2. The display device of claim 1, wherein the substrate comprises:
a first region where the display layer is disposed;
a second region bending and extending from the first region; and
a third region connected to the second region and overlapping the first region.

3. The display device of claim 2, further comprising:
a second adhesive layer disposed between the third region and the cover spacer,
wherein the first adhesive layer is disposed between the first region and the cover spacer.

4. The display device of claim 3, wherein the edge of the first adhesive layer, the edge the cover spacer, and an edge of the second adhesive layer are aligned with each other.

5. The display device of claim 3, wherein the edges of the cover spacer and an edge of the second adhesive layer are aligned with each other.

6. The display device of claim 5, wherein the edge of the first adhesive layer and the edge of the cover spacer are spaced apart from each other.

7. The display device of claim 6, wherein the edge of the first adhesive layer does not overlap the edge of the cover spacer.

8. The display device of claim 3, wherein the second adhesive layer covers the cover spacer.

9. The display device of claim 3, wherein the second adhesive layer exposes at least a portion of the cover spacer.

10. The display device of claim 9, wherein the cover spacer comprises:
a first cover region overlapping the second adhesive layer; and
a second cover region exposed by the second adhesive layer.

11. The display device of claim 1, further comprising:
a support plate positioned between the substrate and the cover spacer.

12. A display device comprising:
a substrate including a first region, a second region, and a third region;
a display layer disposed on the first region of the substrate;
a cover spacer disposed between the first region and the third region, and comprising metal; and
a second adhesive layer disposed between the cover spacer and the third region,
wherein at least a portion of the second adhesive layer and the cover spacer have a same shape as each other.

13. The display device of claim 12, wherein the second region extends from the first region and is bent, and
the third region is connected to the second region and overlaps a rear surface of the first region.

14. The display device of claim 13, further comprising:
a first adhesive layer positioned between the first region and the cover spacer.

15. The display device of claim 14, wherein edges of the first adhesive layer, the cover spacer, and the second adhesive layer are aligned with each other.

16. The display device of claim 14, wherein an edge of the cover spacer and an edge of the second adhesive layer are aligned with each other.

17. The display device of claim 16, wherein an edge of the first adhesive layer and the edge of the cover spacer are spaced apart from each other.

18. The display device of claim 17, wherein the edge of the first adhesive layer does not overlap the edge of the cover spacer.

19. The display device of claim 12, wherein the second adhesive layer completely covers the cover spacer.

20. The display device of claim 12, wherein the second adhesive layer exposes at least a portion of the cover spacer.
